(19) United States
(12) Patent Application Publication
(10) Pub. No.: US 2023/0004357 A1
(43) Pub. Date: Jan. 5, 2023

(54) RANDOM NUMBER GENERATING METHOD AND RANDOM NUMBER GENERATOR

(71) Applicant: TSINGHUA UNIVERSITY, Beijing (CN)

(72) Inventors: Huaqiang WU, Beijing (CN); Bohan LIN, Beijing (CN); Bin GAO, Beijing (CN); Jianshi TANG, Beijing (CN); He QIAN, Beijing (CN)

(73) Assignee: TSINGHUA UNIVERSITY, Beijing (CN)

(21) Appl. No.: 17/779,834

(22) PCT Filed: Nov. 13, 2020
(86) PCT No.: PCT/CN2020/128565

§ 371 Date: May 25, 2022

(30) Foreign Application Priority Data
Dec. 5, 2019 (CN) 201911233504.7

(51) Int. Cl. G06F 7/58

(52) U.S. Cl. CPC G06F 7/588

(57) ABSTRACT

A method for generating a random number and a random number generator are provided. The method for generating a random number includes: performing n writing operations on at least one analog resistive random access memory, where each of the n writing operations includes applying at least one writing operation pulse to change a conductance value of an operated analog resistive access memory; and generating the random number based on n writing operation pulse numbers respectively corresponding to the n writing operations, where n is a positive integer. The method for generating a random number generates random numbers based on the analog characteristics of the analog resistive random access memory, the generated random number does not need back-end correction, and have both high speed and high reliability.

The present application claims priority of Chinese Patent Application No. 201911233504.7, filed on Dec. 5, 2019, and the entire content disclosed by the Chinese patent application is incorporated herein by reference as part of the present application.

### TECHNICAL FIELD

Embodiments of the present disclosure relate to a method for generating a random number and a random number generator.

### BACKGROUND

Random number generators can be divided into pseudo random number generators (PRNG) and true random number generators (TRNG). Both the PRNG and the TRNG can be used to generate high-entropy random numbers. The PRNG can only generate random sequences having a limited length, while the TRNG can generate random numbers by extracting inherent randomness of some circuits with special structures, so that the length of the random sequence generated by the TRNG is not limited. At present, in many important fields, such as encryption (to ensure the security of a large amount of information in high-speed communication), simulation (randomly selecting a large number of possible situations for simulation), and artificial intelligence, there is a great demand for random numbers, and the requirements for the randomness of these random numbers are also very high. In this case, the TRNG is difficult to be replaced by the PRNG, and the TRNG has broad application prospects.

### SUMMARY

At least one embodiment of the present disclosure provides a method for generating a random number, comprising: performing n writing operations on at least one analog resistive random access memory, where each of the n writing operations comprises applying at least one writing operation pulse to change a conductance value of an operated analog resistive access memory; and generating the random number based on n writing operation pulse numbers respectively corresponding to the n writing operations, where n is a positive integer.

For example, in the method for generating a random number provided by at least one embodiment of the present disclosure, an m-th writing operation of the n writing operations comprises a set operation, and at least one writing operation pulse corresponding to the m-th writing operation comprises at least one set pulse, m is a positive integer, 1≤m≤n, and the set operation comprises: sequentially applying the at least one set pulse to the operated analog resistive random access memory until the conductance value of the operated analog resistive random access memory is gradually increased from a set initial conductance value to a set state conductance value.

For example, in the method for generating a random number provided by at least one embodiment of the present disclosure, an m-th writing operation of the n writing operations comprises a set operation, and at least one writing operation pulse corresponding to the m-th writing operation comprises at least one set pulse, m is a positive integer, 1≤m≤n, and the set operation comprises: obtaining a set pulse number threshold; and sequentially applying the at least one set pulse to the operated analog resistive random access memory until the conductance value of the operated analog resistive random access memory is gradually increased from a set initial conductance value to a set state conductance value or a quantity of the at least one set pulse reaches the set pulse number threshold.

For example, in the method for generating a random number provided by at least one embodiment of the present disclosure, the m-th writing operation further comprises a reset operation, the at least one writing operation pulse corresponding to the m-th writing operation further comprises at least one reset pulse, and the reset operation comprises: sequentially applying the at least one reset pulse to the operated analog resistive random access memory until the conductance value of the operated analog resistive random access memory is gradually decreased from the set state conductance value to a reset target conductance value.

For example, in the method for generating a random number provided by at least one embodiment of the present disclosure, the m-th writing operation further comprises a reset operation, the at least one writing operation pulse corresponding to the m-th writing operation further comprises at least one reset pulse, and the reset operation comprises: obtaining a reset pulse number threshold; and sequentially applying the at least one reset pulse to the operated analog resistive random access memory until the conductance value of the operated analog resistive random access memory is gradually decreased from the set state conductance value to a reset target conductance value or a quantity of the at least one reset pulse reaches the reset pulse number threshold.

For example, in the method for generating a random number provided by at least one embodiment of the present disclosure, the set initial conductance value and the reset target conductance value are equal.

For example, in the method for generating a random number provided by at least one embodiment of the present disclosure, an m-th writing operation of the n writing operations comprises a reset operation, and at least one writing operation pulse corresponding to the m-th writing operation comprises at least one reset pulse, m is a positive integer, 1≤m≤n, and the reset operation comprises: sequentially applying the at least one reset pulse to the operated analog resistive random access memory until the conductance value of the operated analog resistive random access memory is gradually decreased from a set state conductance value to a reset target conductance value.

For example, in the method for generating a random number provided by at least one embodiment of the present disclosure, an m-th writing operation of the n writing operations comprises a reset operation, and at least one writing operation pulse corresponding to the m-th writing operation comprises at least one reset pulse, m is a positive integer, and 1≤m≤n, and the reset operation comprises: obtaining a reset pulse number threshold; and sequentially applying the at least one reset pulse to the operated analog resistive random access memory until the conductance value of the operated analog resistive random access memory is gradually decreased from a set state conductance value to a reset target conductance value or a quantity of the at least one reset pulse reaches the reset pulse number threshold.

For example, in the method for generating a random number provided by at least one embodiment of the present disclosure, the generating the random number based on the n writing operation pulse numbers respectively corresponding to the n writing operations comprises: obtaining n intermediate numbers based on the n writing operation pulse numbers respectively corresponding to the n writing operations; and generating the random number according to the n intermediate numbers.

For example, in the method for generating a random number provided by at least one embodiment of the present disclosure, for an i-th writing operation of the n writing operations, i is a positive integer and 1≤i≤n, and the n intermediate numbers comprise an i-th intermediate number corresponding to the i-th writing operation, the n writing operation pulse numbers comprise an i-th writing operation pulse number corresponding to the i-th writing operation, in a case where the i-th writing operation only comprises a set operation, the i-th writing operation pulse number comprises a set pulse number corresponding to the set operation, and the i-th intermediate number is obtained by performing a first computation on the set pulse number, or in a case where the i-th writing operation only comprises a reset operation, the i-th writing operation pulse number comprises a reset pulse number corresponding to the reset operation, and the i-th intermediate number is obtained by performing a second computation on the reset pulse number, or in a case where the i-th writing operation comprises a set operation and a reset operation, the i-th writing operation pulse number comprises a set pulse number corresponding to the set operation and a reset pulse number corresponding to the reset operation, a computation result is obtained by performing a third computation on the set pulse number and the reset pulse number, and the i-th intermediate number is obtained by performing a fourth computation on the computation result.

For example, in the method for generating a random number provided by at least one embodiment of the present disclosure, the third computation comprises a summation operation.

For example, in the method for generating a random number provided by at least one embodiment of the present disclosure, the first computation, the second computation, and the fourth computation comprise a modulo 2^{L} computation, wherein L is a positive integer, and the generating the random number according to the n intermediate numbers comprises: taking the n intermediate numbers as n digits of an n-bit 2^{L}-ary number, respectively, and generating the random number based on the n-bit 2^{L}-ary number.

At least one embodiment of the present disclosure provides a random number generator, comprising: at least one analog resistive random access memory; a writing circuit, coupled to the at least one analog resistive random access memory and configured to perform n writing operations on the at least one analog resistive random access memory, where each of the n writing operations comprises applying at least one writing operation pulse to change a conductance value of an operated analog resistive random access memory; a counter, coupled to the writing circuit and configured to count writing operation pulses corresponding to the n writing operations to obtain n writing operation pulse numbers corresponding to the n writing operations, respectively; and an output circuit, coupled to the counter and configured to generate a random number based on the n writing operation pulse numbers, where n is a positive integer.

For example, in the random number generator provided by at least one embodiment of the present disclosure, the writing circuit comprises a pulse generation circuit, a comparator, and a controller, an m-th writing operation of the n writing operations comprises a set operation, at least one writing operation pulse corresponding to the m-th writing operation comprises at least one set pulse, m is a positive integer, and 1≤m≤n, the n writing operation pulse numbers comprise an m-th writing operation pulse number corresponding to the m-th writing operation, the controller is configured to control the pulse generation circuit to generate and apply the at least one set pulse to the operated analog resistive random access memory, so that the conductance value of the operated analog resistive random access memory is gradually increased from a set initial conductance value to a set state conductance value, and configured to control the counter to count the at least one set pulse to obtain an m-th set pulse number, and the m-th writing operation pulse number comprises the m-th set pulse number; the comparator is configured to compare the conductance value of the operated analog resistive random access memory with a set state conductance value threshold to obtain a set comparison result; and the controller is further configured to control the counter to output the m-th set pulse number obtained by counting to the output circuit in a case where the set comparison result indicates that the conductance value of the operated analog resistive random access memory is increased to the set state conductance value.

For example, in the random number generator provided by at least one embodiment of the present disclosure, the writing circuit comprises a pulse generation circuit, a comparator, and a controller, an m-th writing operation of the n writing operations comprises a set operation, at least one writing operation pulse corresponding to the m-th writing operation comprises at least one set pulse, m is a positive integer, and 1≤m≤n, the n writing operation pulse numbers comprise an m-th writing operation pulse number corresponding to the m-th writing operation, the controller is configured to control the pulse generation circuit to generate and apply the at least one set pulse to the operated analog resistive random access memory, so that the conductance value of the operated analog resistive random access memory is gradually increased from a set initial conductance value to a set state conductance value, and configured to control the counter to count the at least one set pulse to obtain an m-th set pulse number, and the m-th writing operation pulse number comprises the m-th set pulse number; the comparator is configured to compare the conductance value of the operated analog resistive random access memory with a set state conductance value threshold to obtain a set comparison result; the controller is further configured to obtain a set pulse number threshold, and control the counter to output the m-th set pulse number obtained by counting to the output circuit in a case where the set comparison result indicates that the conductance value of the operated analog resistive random access memory is increased to the set state conductance value or the m-th set pulse number reaches the set pulse number threshold.

For example, in the random number generator provided by at least one embodiment of the present disclosure, the m-th writing operation further comprises a reset operation, and the writing operation pulse further comprises a reset pulse, the controller is configured to control the pulse generation circuit to generate and apply at least one reset pulse to the operated analog resistive random access memory, so that the conductance value of the operated analog resistive random access memory is gradually decreased from the set state conductance value to a reset target conductance value, and configured to control the counter to count the at least one reset pulse to obtain an m-th reset pulse number, and the m-th writing operation pulse number further comprises the m-th reset pulse number; the comparator is configured to compare the conductance value of the operated analog resistive random access memory with a reset target conductance value threshold to obtain a reset comparison result; the controller is further configured to control the counter to output the m-th reset pulse number obtained by counting to the output circuit in a case where the reset comparison result indicates that the conductance value of the operated analog resistive random access memory is decreased to the reset target conductance value.

For example, in the random number generator provided by at least one embodiment of the present disclosure, the m-th writing operation further comprises a reset operation, and the writing operation pulse further comprises a reset pulse, the controller is configured to control the pulse generation circuit to generate and apply at least one reset pulse to the operated analog resistive random access memory, so that the conductance value of the operated analog resistive random access memory is gradually decreased from the set state conductance value to a reset target conductance value, and configured to control the counter to count the at least one reset pulse to obtain an m-th reset pulse number, and the m-th writing operation pulse number further comprises the m-th reset pulse number; the comparator is configured to compare the conductance value of the operated analog resistive random access memory with a reset target conductance value threshold to obtain a reset comparison result; the controller is further configured to obtain a reset pulse number threshold, and control the counter to output the m-th reset pulse number obtained by counting to the output circuit in a case where the reset comparison result indicates that the conductance value of the operated analog resistive random access memory is decreased to the reset target conductance value or the m-th reset pulse number reaches the reset pulse number threshold.

For example, in the random number generator provided by at least one embodiment of the present disclosure, the set initial conductance value and the reset target conductance value are equal.

For example, in the random number generator provided by at least one embodiment of the present disclosure, the writing circuit comprises a pulse generation circuit, a comparator, and a controller, an m-th writing operation of the n writing operations comprises a reset operation, at least one writing operation pulse corresponding to the m-th writing operation comprises at least one reset pulse, m is a positive integer, and 1≤m≤n, the n writing operation pulse numbers comprise an m-th writing operation pulse number corresponding to the m-th writing operation, the controller is configured to control the pulse generation circuit to generate and apply the at least one reset pulse to the operated analog resistive random access memory, so that the conductance value of the operated analog resistive random access memory is gradually decreased from a set state conductance value to a reset target conductance value, and configured to control the counter to count the at least one reset pulse to obtain a m-th reset pulse number, and the m-th writing operation pulse number comprises the m-th reset pulse number; the comparator is configured to compare the conductance value of the operated analog resistive random access memory with a reset target conductance value threshold to obtain a reset comparison result; the controller is further configured to control the counter to output the m-th reset pulse number obtained by counting to the output circuit in a case where the reset comparison result indicates that the conductance value of the operated analog resistive random access memory is decreased to the reset target conductance value.

For example, in the random number generator provided by at least one embodiment of the present disclosure, the writing circuit comprises a pulse generation circuit, a comparator, and a controller, an m-th writing operation of the n writing operations comprises a reset operation, at least one writing operation pulse corresponding to the m-th writing operation comprises at least one reset pulse, m is a positive integer, and 1≤m≤n, the n writing operation pulse numbers comprise an m-th writing operation pulse number corresponding to the m-th writing operation, the controller is configured to control the pulse generation circuit to generate and apply the at least one reset pulse to the operated analog resistive random access memory, so that the conductance value of the operated analog resistive random access memory is gradually decreased from a set state conductance value to a reset target conductance value, and configured to control the counter to count the at least one reset pulse to obtain an m-th reset pulse number, and the m-th writing operation pulse number comprises the m-th reset pulse number; the comparator is configured to compare the conductance value of the operated analog resistive random access memory with a reset target conductance value threshold to obtain a reset comparison result; the controller is further configured to obtain a reset pulse number threshold, and control the counter to output the m-th reset pulse number obtained by counting to the output circuit in a case where the reset comparison result indicates that the conductance value of the operated analog resistive random access memory is decreased to the reset target conductance value or the m-th reset pulse number reaches the reset pulse number threshold.

For example, in the random number generator provided by at least one embodiment of the present disclosure, the output circuit is configured to: obtain n intermediate numbers based on writing operation pulse numbers of the n writing operations, and generate the random number based on the n intermediate numbers.

For example, in the random number generator provided by at least one embodiment of the present disclosure, for an i-th writing operation, i is a positive integer and 1≤i≤n, and the output circuit is configured to: in a case where the i-th writing operation only comprises a set operation, perform a first computation on a quantity of set pulses of the set operation to obtain an intermediate number corresponding to the i-th writing operation, or in a case where the i-th writing operation only comprises a reset operation, perform a second computation on a quantity of reset pulses of the reset operation to obtain an intermediate number corresponding to the i-th writing operation, or in a case where the i-th writing operation comprises a set operation and a reset operation, perform a third computation on a quantity of set pulses of the set operation and a quantity of reset pulses of the reset operation to obtain a computation result, and perform a fourth computation on the computation result to obtain an intermediate number corresponding to the i-th writing operation.

For example, in the random number generator provided by at least one embodiment of the present disclosure, the output circuit is configured to accumulate the quantity of set pulses of the set operation and the quantity of reset pulses of the reset operation to achieve the third computation.

For example, in the random number generator provided by at least one embodiment of the present disclosure, the output circuit is configured to perform a modulo 2^{L} computation to achieve the first computation, the second computation, and the fourth computation, L being a positive integer, respectively take the n intermediate numbers as digits of an n-bit 2^{L}-ary number, and generate the random number based on the n-bit 2^{L}-ary number.

For example, in the random number generator provided by at least one embodiment of the present disclosure, the counter comprises a 1-bit counter, and the output circuit comprises an n-bit D-trigger, the 1-bit counter is configured to perform modulo-2 counting on writing operation pulses corresponding to the n writing operations, to obtain the n writing operation pulse numbers corresponding to the n writing operations; and the n-bit D-trigger is configured to output the n writing operation pulse numbers as the random number.

### BRIEF DESCRIPTION OF THE DRAWINGS

In order to more clearly illustrate the technical solutions of the embodiments of the present disclosure, the accompanying drawings in relevant embodiments will be described briefly in the following. It is apparent that the drawings described below are only related to some embodiments of the disclosure and are not intended to limit the present disclosure.

FIG. 1 is a structural schematic diagram of an analog resistive random access memory provided by at least one embodiment of the present disclosure;

FIG. 2 is a schematic diagram of analog characteristics of an analog resistive random access memory provided by at least one embodiment of the present disclosure;

FIG. 3 is a schematic diagram of statistical distribution of writing pulse numbers of an analog resistive random access memory provided by at least one embodiment of the present disclosure;

FIG. 4 is a flow diagram of a method for generating a random number provided by at least one embodiment of the present disclosure;

FIG. 5 is a flow diagram of an example of an m-th writing operation in a method for generating a random number provided by at least one embodiment of the present disclosure;

FIG. 6 is a schematic diagram of a random number generated by the example shown in FIG. 5;

FIG. 7 is a flow diagram of another example of an m-th writing operation in a method for generating a random number provided by at least one embodiment of the present disclosure;

FIG. 8 is a flow diagram of further another example of an m-th writing operation in a method for generating a random number provided by at least one embodiment of the present disclosure;

FIG. 9 is a schematic diagram of a random number generated by the example shown in FIG. 8;

FIG. 10 is a flow diagram of still another example of an m-th writing operation in a method for generating a random number provided by at least one embodiment of the present disclosure;

FIG. 11 is a flow diagram of further another example of an m-th writing operation in a method for generating a random number provided by at least one embodiment of the present disclosure;

FIG. 12 is a schematic diagram of a random number generated by the example shown in FIG. 11;

FIG. 13 is a flow diagram of yet another example of an m-th writing operation in a method for generating a random number provided by at least one embodiment of the present disclosure;

FIG. 14 is a schematic block diagram of a random number generator provided by at least one embodiment of the present disclosure;

FIG. 15 is a schematic block diagram of an example of a random number generator provided by at least one embodiment of the present disclosure; and

FIG. 16 is a schematic block diagram of a specific example of a random number generator provided by at least one embodiment of the present disclosure.

### DETAILED DESCRIPTION

In order to make objects, technical solutions, and advantages of the embodiments of the present disclosure apparent, the technical solutions of the embodiments of the present disclosure will be described in a clearly and fully understandable way in connection with the drawings related to the embodiments of the present disclosure. Apparently, the described embodiments are just a part but not all of the embodiments of the present disclosure. Based on the described embodiments of the present disclosure, those skilled in the art can obtain other embodiment(s), without any inventive work, which should be within the scope of the present disclosure.

Unless otherwise defined, all the technical and scientific terms used herein have the same meanings as commonly understood by one of ordinary skill in the art to which the present disclosure belongs. The terms “first,” “second,” etc., which are used in the present disclosure, are not intended to indicate any sequence, amount, or importance, but distinguish various components. Also, the terms such as “a,” “an,” or “the” etc., are not intended to limit the amount, but indicate the existence of at least one. The terms “comprise,” “comprising,” “include,” “including,” etc., are intended to specify that the elements or the objects stated before these terms encompass the elements or the objects and equivalents thereof listed after these terms, but do not preclude the other elements or objects. The phrases “connect”, “connected”, etc., are not intended to define a physical connection or mechanical connection, but may include an electrical connection, directly or indirectly. “On,” “under,” “right,” “left” and the like are only used to indicate relative position relationship, and when the absolute position of the object which is described is changed, the relative position relationship may be changed accordingly.

At present, the TRNG can be divided into two types. The first type is the TRNG based on a transistor circuit, such as TRNG based on latch structure metastable state and TRNG based on ring oscillator; the second type is the TRNG based on new memory, such as TRNG based on magnetic memory and TRNG based on resistive random access memory. The first type of TRNG usually needs many additional calibration circuits to ensure the effective work of TRNG, so the first type of TRNG has a large area cost; in the second type of TRNG, the TRNG based on magnetic memory usually uses complex material system, so it is difficult to manufacture the TRNG based on magnetic memory. In contrast, the TRNG based on resistive random access memory in the second type of TRNG has a circuit design that is highly similar to the memory module, and the material system of the TRNG based on resistive random access memory is compatible with micro-nano process technology, so the TRNG based on resistive random access memory can better overcome the above shortcomings.

The TRNG based on resistive random access memory generates random numbers based on the inherent randomness of the resistive random access memory. At present, the TRNG based on resistive random access memory is implemented into two technical solutions, and the two technical solutions generate random numbers respectively by using the read noise characteristics and switching characteristics of the resistive random access memory. In the first solution, the resistance values read out by the resistive random access memory have the characteristics of random jitter under thermal noise interference, the resistance values read out at two different moments are compared, and random numbers are generated based on the comparison results. The second technical solution utilizes the volatile characteristic of the resistive random access memory, that is, the characteristic that the resistive random access memory will automatically switch back to the “off” state after a period of time after being adjusted to the “on” state, to generate the random numbers by recording the time when the resistive random access memory is maintained in the “on” state. However, the TRNG based on the read noise characteristics of the resistive random access memory has high requirements for the precision of the read circuit and has uncertainty in the behavior of the read noise, and the generated random numbers need to be modified at the back end (for example, von Neumann correction, multiple XOR, etc.), so the reliability and output randomness of the TRNG based on the read noise characteristics of the resistive random access memory need to be further improved. The TRNG based on the switching characteristics of the resistive random access memory needs to wait for the resistive random access memory to spontaneously complete the state switching, and therefore, has the problems of slow speed (for example, the throughput is usually in the order of 1 kbit/sec˜10 kbit/sec) and the insufficient erasable times (for example, the erasable times are usually in the order of 10⁶-10⁷) of the resistive random access memory itself.

In summary, the existing TRNG based on resistive random access memory cannot have the two very important characteristics of high speed and high reliability.

At least one embodiment of the present disclosure provides a method for generating a random number, which includes: performing n writing operations on at least one analog resistive random access memory, in which each of the n writing operations includes applying at least one writing operation pulse to change a conductance value of an operated analog resistive access memory; and generating a random number based on n writing operation pulse numbers respectively corresponding to the n writing operations, in which n is a positive integer.

At least one embodiment of the present disclosure further provides a random number generator corresponding to the above method for generating the random number.

The method for generating a random number and the random number generator provided by the embodiments of the present disclosure generate a random number based on analog characteristics of the writing operations of the analog resistive random access memory, and the generated random number does not need to be modified at the back end. In at least one example, the throughput of generating the random number by a single analog resistive random access memory can reach 1 Mbit/sec, and the erasable times of the analog resistive random access memory can reach the order of 10¹¹, in these cases, the method for generating a random number and the random number generator provided by the embodiments of the present disclosure make up for the deficiencies of the above-mentioned method of generating random numbers based on the read noise characteristics and switching characteristics of the resistive random access memory, and have both high speed and high reliability.

Embodiments and examples thereof of the present disclosure are described in detail below in combination with the accompanying drawings.

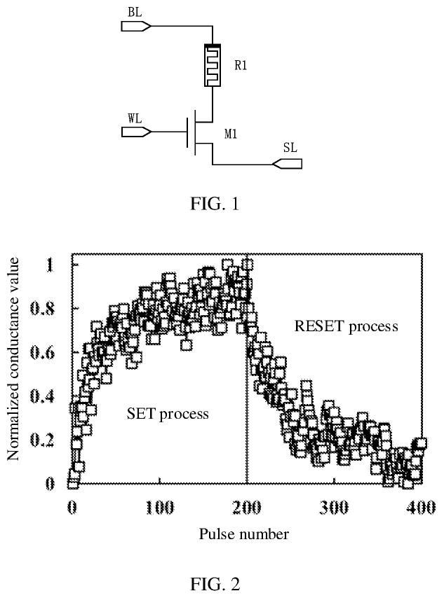

FIG. 1 is a structural schematic diagram of an analog resistive random access memory provided by at least one embodiment of the present disclosure. As shown in FIG. 1, the analog resistive random access memory adopts a 1T1R structure as an example, that is, the analog resistive random access memory includes a transistor M1 and a resistive component R1.

It should be noted that the transistors used in the embodiments of the present disclosure can be thin-film transistors or field-effect transistors (for example, MOS field-effect transistors) or other switching devices with the same characteristics, and the source electrode and the drain electrode of the adopted transistor can be symmetrical in structure, so there is no difference between the source electrode and the drain electrode of the adopted transistor in structure. In the embodiments of the present disclosure, in order to distinguish the two electrodes of a transistor other than the gate electrode, it is directly described that one electrode is a first electrode and the other electrode is a second electrode.

The embodiments of the present disclosure does not limit the type of the adopted transistor, for example, in a case where the transistor M1 adopts an N-type transistor, a gate electrode of the transistor M1 is connected to a word line end WL, for example, when the word line end WL inputs a high level, the transistor M1 is turned on; a first electrode of the transistor M1 may be a source electrode and is configured to be connected to a source line end SL, for example, the transistor M1 can receive a reset pulse through the source line end SL; a second electrode of transistor M1 may be a drain electrode and is configured to be connected to a second electrode (e.g., negative electrode) of the resistive component R1, and a first electrode (e.g., positive electrode) of the resistive component R1 is connected to a bit line end BL. For example, the resistive component R1 can receive a set pulse through the bit line end BL. For example, in a case where the transistor M1 adopts a P-type transistor, a gate electrode of the transistor M1 is connected to a word line end WL, for example, when the word line end WL inputs a low level, the transistor M1 is turned on; a first electrode of the transistor M1 may be a source electrode and is configured to be connected to a source line end SL, for example, the transistor M1 can receive a set pulse through the source line end SL; a second electrode of the transistor M1 may be a drain electrode and is configured to be connected to a second electrode (e.g., negative electrode) of the resistive component R1, and a first electrode (e.g., positive electrode) of the resistive component R1 is connected to a bit line end BL, for example, the resistive component R1 can receive a reset pulse through the bit line end BL. It should be noted that in the case where the N-type transistor is used, when the bit line end BL receives the set pulse, the source line end SL is grounded, and when the source line end SL receives the reset pulse, the bit line end BL is grounded. It should be noted that in the case where the P-type transistor is used, when the bit line end BL receives the reset pulse, the source line end SL is connected to a power supply voltage, and when the source line end SL receives the set pulse, the bit line end BL is connected to the power supply voltage. It should be noted that the structure of the resistive random access memory may also be implemented as other structures, and the embodiments of the present disclosure are not limited in this aspect. The following embodiments are illustrated by taking the transistor M1 adopting the N-type transistor as an example.

Writing operations such as set operations and/or reset operations can be implemented by applying writing operation pulses to the analog resistive random access memory to change the conductance value of the analog resistive random access memory. The function of the word line end WL is to apply a corresponding voltage to the gate electrode of the transistor M1, thus controlling the transistor M1 to be turned on or turned off. When performing a writing operation on an analog resistive random access memory, such as performing a set operation or a reset operation, the transistor M1 needs to be turned on first, that is, a turn-on voltage needs to be applied to the gate electrode of the transistor M1 through the word line end WL. After the transistor M1 is turned on, for example, the source line end SL can be controlled to be grounded, and a set pulse is applied to the bit line end BL as a writing operation pulse to increase the conductance value of the analog resistive random access memory. For another example, the bit line end BL can be controlled to be grounded, and a reset pulse is applied to the source line end SL as a writing operation pulse to reduce the conductance value of the analog resistive random access memory.

It should be noted that, in the embodiments of the present disclosure, the writing operation of applying at least one set pulse to the analog resistive random access memory to increase the conductance value of the analog resistive random access memory is called as a set operation, and the writing operation of applying at least one reset pulse to the analog resistive random access memory to reduce the conductance value of the analog resistive random access memory is called as a reset operation. The following embodiments are the same as those described herein, and similar portions will not be repeated again.

It should also be noted that, in the embodiments of the present disclosure, the at least one writing operation pulse applied in the same writing operation that is performed on the analog resistive random access memory is the same, which is exemplary and not a limitation of the present disclosure. Moreover, in the embodiments of the present disclosure, the writing operation pulses applied in different writing operations that is performed on the analog resistive random access memory are the same, which is exemplary and not a limitation of the present disclosure.

In the present disclosure, the analog resistive random access memory refers to a resistive random access memory whose conductance value can continuously change, and the analog characteristic refers to the characteristic that the conductance value can continuously change. The following embodiments are the same as those described herein, and similar portions will not be repeated again. During the writing operation, the conductance value of the analog resistive random access memory gradually changes under the action of the writing operation pulse. For example, conductance values of some analog resistive random access memory can be gradually increased from 0.1 μS (micro Siemens) to 10 μS under the action of the writing operation pulse. For example, FIG. 2 illustrates a change process of the conductance value of an analog resistive random access memory under the action of pulses provided by at least one embodiment of the present disclosure. In FIG. 2, under the action of 200 identical set pulses, the conductance value of the analog resistive random access memory is gradually increased (that is, the SET process in FIG. 2), and under the action of 200 identical reset pulses, the conductance value of the analog resistive random access memory is gradually decreased (that is, the RESET process in FIG. 2).

In a case where a writing operation is performed on the analog resistive random access memory, under the action of the same writing operation pulse, the change amount of the conductance value of the analog resistive random access memory is uncertain and random. For example, as shown in FIG. 2, for 200 identical set pulses, the conductance value of the analog resistive random access memory has different increase amounts, and for 200 identical reset pulses, the conductance value of the analog resistive random access memory also has different decrease amounts. Therefore, the number of writing operation pulses required for the analog resistive random access memory to achieve a specific writing operation (that is, the conductance value of the analog resistive random access memory is adjusted from a specific initial value to a specific target value) is uncertain and random. It should be noted that the increase amount and decrease amount may also be negative.

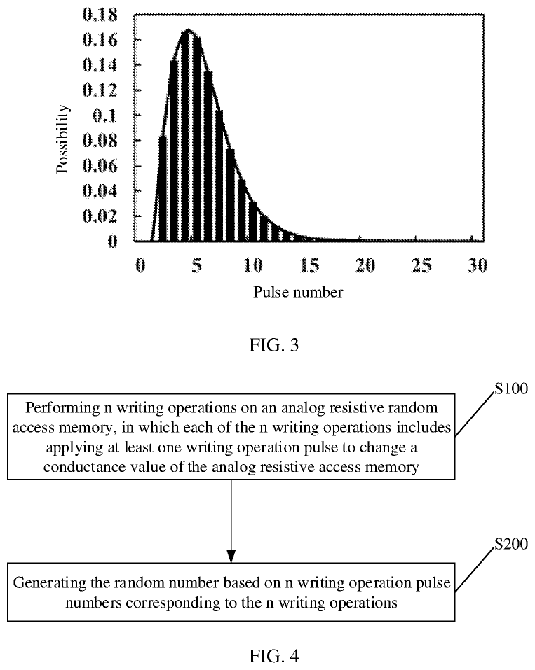

FIG. 3 illustrates the statistical distribution of writing pulse numbers of an analog resistive random access memory provided by at least one embodiment of the present disclosure, the abscissa is the pulse number, and the ordinate is the probability of corresponding pulse number to achieve the writing operation. The pulse is a rectangular pulse with a pulse width of 50 ns (nanoseconds), a duty cycle of 50%, and an amplitude of 1.9V (volts). The writing operation includes a set operation that makes the conductance value of the analog resistive random access memory increase gradually from a conductance value less than 10 μS (micro Siemens) to a conductance value greater than 20 μS, and includes a reset operation that makes the conductance value of the analog resistive random access memory decrease gradually from a conductance value greater than 20 μS to a conductance value less than 10 μS. FIG. 3 shows the statistical distribution of the pulse number in 20480 cycles (the process of completing a set operation and a reset operation is defined as one cycle). It can be seen from FIG. 3 that in the 20480 cycles, the possibility of the pulse number being 5 (that is, in a single cycle, the sum of the pulse number in the set operation and the pulse number in the reset operation is 5) is the largest. It can be seen from FIG. 3 that the pulse number required for the analog resistive random access memory to achieve a writing operation is random. Therefore, the randomness of the pulse number required for the analog resistive random access memory to achieve a writing operation can be used to implement a true random number generator.

At least one embodiment of the present disclosure provides a method for generating a random number, and FIG. 4 is a flow diagram of the method for generating a random number. The method for generating a random number can be implemented by means of software, hardware, firmware, or any combination thereof. The method for generating a random number provided by the embodiments of the present disclosure will be described in detail below with reference to FIG. 4. As shown in FIG. 4, the method for generating a random number includes a step S100 and a step S200.

Step S100: performing n writing operations on at least one analog resistive random access memory, in which each of the n writing operations includes applying at least one writing operation pulse to change a conductance value of an operated analog resistive access memory.

Step S200: generating the random number based on n writing operation pulse numbers corresponding to the n writing operations.

For example, n is a positive integer, and the random number is a true random number.

It should be noted that the random number may be a random number in a binary form (that is, the random number is a binary number composed of 0 and 1), or be a random number in other forms, such as a random number in a quaternary form, a decimal form, a hexadecimal form, or other forms. In the embodiments of the present disclosure, in order to describe the technical solutions of the present disclosure more clearly, the random number refers to the random number in a binary form, which is exemplary and not a limitation of the present disclosure.

According to the total number of digits of the random number that needs to be generated and the specific manner in which the random number is generated based on each writing operation pulse number, n can be determined. For example, a random number with a length of 12 bits needs to be generated, and a modulo 2 value (that is, 0 or 1, the 0 or 1 can be used to represent the Odevity of the writing operation pulse number) of each writing operation pulse number can be used to generate the random number, that is, 1 bit of the random number can be generated based on each writing operation pulse number, and n may be a positive integer greater than or equal to 12. For example, a random number with a length of 12 bits needs to be generated, and a modulo 4 value (that is, 0, 1, 2, or 3) of each writing operation pulse number is used to generate the random number. For example, each modulo 4 value can be represented by a 2-bit binary number, that is, 2 bits of the random number can be generated based on each writing operation pulse number, in this case, n may be a positive integer greater than or equal to 6. It should be noted that the total number of digits of the random number that needs to be generated depends on the actual situation, which is not limited in the embodiments of the present disclosure.

The process of generating the random number will be described in detail below.

For the step S100, in each writing operation, a writing operation pulse is applied to at least one analog resistive random access memory, so that the conductance value of the operated analog resistive random access memory gradually changes, and the number of the applied writing operation pulses is recorded. In different embodiments, the above method can be performed on the same analog resistive random access memory, or on different analog resistive random access memories. For the latter case, for example, a part of the n writing operations is performed on one analog resistive random access memory, and the other part of the n writing operations is performed on another analog resistive random access memory. In different examples, the writing operation may include only a set operation, or include only a reset operation, or include both a set operation and a reset operation. In a case where the writing operation is a set operation, the writing operation pulse is a set pulse, in this case, the set pulse is applied to the operated analog resistive random access memory, so that the conductance value of the operated analog resistive random access memory is gradually increased; and in a case where the writing operation is a reset operation, the writing operation pulse is a reset pulse, in this case, the reset pulse is applied to the operated analog resistive random access memory, so that the conductance value of the operated analog resistive random access memory is gradually decreased.

For example, the writing operation pulse is a rectangular pulse with a pulse width of 50 ns, a duty cycle of 50%, and an amplitude of 2v. The specific parameters of the writing operation pulse can be determined according to the characteristics of the specific analog resistive random access memory, and the embodiments of the present disclosure are not limited in this aspect.

For example, under the action of the set pulse, the conductance value of the operated analog resistive random access memory is gradually increased from a first initial conductance value to a first target conductance value. For example, the first initial conductance value is less than 10 μS, and the first target conductance value is greater than 20 μS. For example, under the action of the reset pulse, the conductance value of the operated analog resistive random access memory is gradually decreased from a second initial conductance value to a second target conductance value, for example, the second initial conductance value is greater than 20 μS, and the second target conductance value is less than 10 μS. For example, under the action of the set pulse, the conductance value of the operated analog resistive random access memory is gradually increased from a third initial conductance value to a third target conductance value, and then, under the action of the reset pulse, the conductance value of the operated resistive random access memory is gradually decreased from the third target conductance value to a fourth target conductance value. For example, the third initial conductance value is less than 10 μS, the third target conductance value is greater than 20 μS, and the fourth target conductance value is less than 10 μS. It should be noted that each of the above-mentioned initial conductance values and each of the above-mentioned target conductance values may be determined according to the characteristics of the specific analog resistive random access memory, and the embodiments of the present disclosure are not limited in this aspect.

For example, in an example of the method for generating a random number provided by the present disclosure, the step S100 may include a step S110.

Step S110: an m-th writing operation of the n writing operations includes a set operation, and at least one writing operation pulse corresponding to the m-th writing operation includes at least one set pulse, m is a positive integer, and 1≤m≤n, the set operation includes: sequentially applying the at least one set pulse to the operated analog resistive random access memory until the conductance value of the operated analog resistive random access memory is gradually increased from a set initial conductance value to a set state conductance value.

For example, the set initial conductance value is less than 10 μS, and the set state conductance value is greater than 20 μS, but the embodiments of the present disclosure are not limited to this. It should be noted that in a case where the n writing operations are all set operations, n set initial conductance values corresponding to the n writing operations may be at least partially different, as long as the n set initial conductance values are all less than 10 μS, and n set state conductance values corresponding to the n writing operations may also be at least partially different, as long as the n set state conductance values are all greater than 20 μS.

For example, in a case where the conductance value of the operated analog resistive random access memory changes to the set state conductance value, the number, which has been recorded, of the applied set pulses can be obtained to obtain the m-th writing operation pulse number corresponding to the m-th writing operation.

For example, FIG. 5 illustrates a flow diagram of the m-th writing operation in the step S110. As shown in FIG. 5, at a step S111, initializing the conductance value of the operated analog resistive random access memory to a set initial conductance value; at a step S112, applying a set pulse to the operated analog resistive random access memory that is initialized; at a step S113, determining whether the conductance value of the operated analog resistive random access memory is increased to the set state conductance value, if yes (Y), ending the m-th writing operation, if not (N), returning to the step S112.

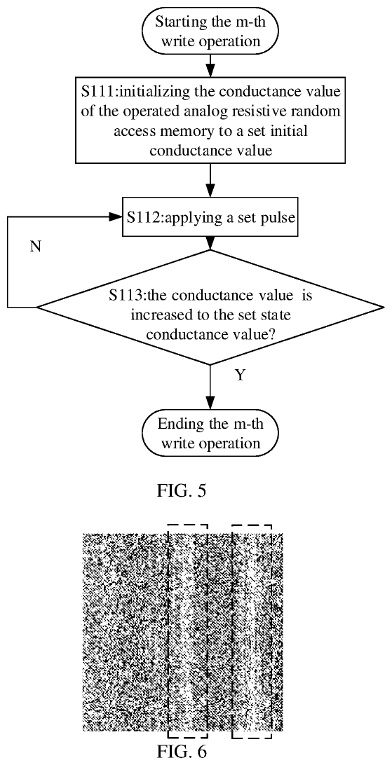

For example, FIG. 6 illustrates a schematic diagram of a random number generated based on the flow of the writing operation shown in FIG. 5. In FIG. 6, the generated random number is a binary random number, the black dot represents 0, and the white dot represents 1. For example, in one example, each black dot represents a set operation and the set pulse number corresponding to the set operation is an even number, and each white dot also represents a set operation but the set pulse number corresponding to the set operation is an odd number. As shown in FIG. 6, the black dots and the white dots in the schematic diagram are basically evenly distributed, which indicates that the generated random numbers are unbiased and random.

In the process of implementing the m-th writing operation of the step S110, because the behavior of the analog resistive random access memory is unstable, it may be difficult to set the analog resistive random access memory. For this case, in some examples, a method of setting a set pulse number threshold can be used to avoid the generation process of the random number from falling into an endless loop, and the method of setting the set pulse number threshold does not affect the randomness of the generated random number. For example, in an example of the method for generating a random number provided by the present disclosure, the step S100 may include a step S120.

Step S120: an m-th writing operation of the n writing operations includes a set operation, and at least one writing operation pulse corresponding to the m-th writing operation includes at least one set pulse, m is a positive integer, and 1≤m≤n, the set operation includes: obtaining a set pulse number threshold; and sequentially applying the at least one set pulse to the operated analog resistive random access memory until the conductance value of the operated analog resistive random access memory is gradually increased from a set initial conductance value to a set state conductance value or a quantity of the at least one set pulse reaches the set pulse number threshold.

For example, the set initial conductance value is less than 10 μS, and the set state conductance value is greater than 20 μS, but the embodiments of the present disclosure are not limited to this.

For example, the set pulse number threshold may be 20, but the embodiments of the present disclosure are not limited to this aspect. The set pulse number threshold may also be 15, 25, . . . 100, 1000, etc.

For example, in a case where the conductance value of the operated analog resistive random access memory changes to the set state conductance value, the quantity of the applied set pulses that has been recorded can be obtained to obtain the m-th writing operation pulse number corresponding to the m-th writing operation, or the quantity of the applied set pulses that has been recorded reaches the set pulse number threshold, in this case, the quantity of the applied set pulses that has been recorded (that is, the set pulse number threshold) is equal to the m-th writing operation pulse number corresponding to the m-th writing operation.

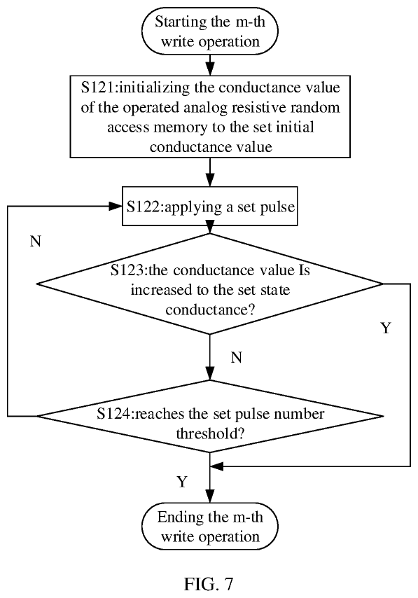

For example, FIG. 7 illustrates a flow diagram of the m-th writing operation in the step S120. As shown in FIG. 7, at a step S121, initializing the conductance value of the operated analog resistive random access memory to the set initial conductance value; at a step S122, applying a set pulse to the operated analog resistive random access memory after initialization; at a step S123, determining whether the conductance value of the operated analog resistive random access memory is increased to the set state conductance value, if yes, ending the m-th writing operation, if not, proceeding to a step S124; at the step S124, determining whether the set pulse number reaches the set pulse number threshold, if yes, ending the m-th writing operation, and if not, returning to the step S122.

In the schematic diagram of FIG. 6, there are two regions with dense white dots (two regions enclosed by the dashed frames), which means that the random number 1 generated in these regions is more than the random number 0. The reason for this phenomenon is that there are differences in the characteristics of different analog resistive random access memories. The writing operation pulse number that needs to be applied when some analog resistive random access memories are set has good randomness, but the writing operation pulse number that needs to be applied when some analog resistive random access memories are reset has poor randomness; while the writing operation pulse number that needs to be applied when some analog resistive random access memories are reset has good randomness, but the writing operation pulse number that needs to be applied when some analog resistive random access memories are set has poor randomness. In this case, each of the n writing operations may include a set operation and a reset operation at the same time, so as to improve the randomness of the generated random number.

For example, in an example of the method for generating a random number provided by the present disclosure, the step S100 may include a step S130.

Step S130: under the premise that the m-th writing operation described in the step S110 or S120 includes a set operation, the m-th writing operation further includes a reset operation, the at least one writing operation pulse corresponding to the m-th writing operation further includes at least one reset pulse, and the reset operation includes: sequentially applying the at least one reset pulse to the operated analog resistive random access memory until the conductance value of the operated analog resistive random access memory is gradually decreased from the set state conductance value to a reset target conductance value.

For example, the set state conductance value is greater than 20 μS, and the reset target conductance value is less than 10 μS, but the embodiments of the present disclosure are not limited to this. It should be noted that in a case where each of the n writing operations includes a set operation and a reset operation, the n set initial conductance values respectively corresponding to the n writing operations may be at least partially different, as long as the n set initial conductance values are all less than 10 μS, and the n set state conductance values respectively corresponding to the n writing operations may also be at least partially different, as long as the n set state conductance values are all greater than 20 μS, and the n reset target conductance values respectively corresponding to the n writing operations may also be at least partially different, as long as the n reset target conductance values are all conductance values less than 10 μS.

For example, in a case where the conductance value of the operated analog resistive random access memory changes to the reset target conductance value, the quantity of the applied reset pulses that has been recorded can be obtained to obtain the m-th reset pulse number corresponding to the m-th writing operation.

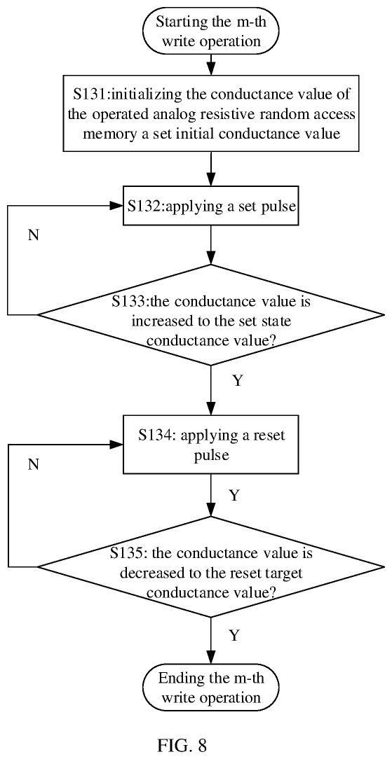

For example, FIG. 8 illustrates a flow diagram of the m-th writing operation in the step S130. As shown in FIG. 8, at a step S131, initializing the conductance value of the operated analog resistive random access memory to a set initial conductance value; at a step S132, applying a set pulse to the operated analog resistive random access memory after initialization; at a step S133, determining whether the conductance value of the operated analog resistive random access memory is increased to the set state conductance value, if yes, proceeding to a step S134, if not, returning to the step S132; at the step S134, applying a reset pulse to the operated analog resistive random access memory; at a step S135, determining whether the conductance value of the operated analog resistive random access memory is decreased to the reset target conductance value, if yes, ending the m-th writing operation, if not, returning to the step S134.

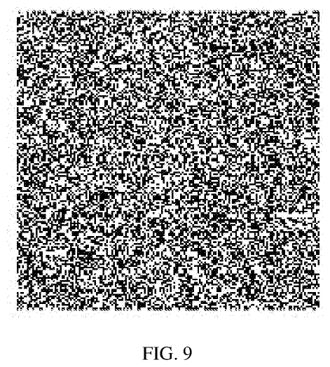

For example, FIG. 9 illustrates a schematic diagram of a random number generated based on the writing operation flow shown in FIG. 8. In FIG. 9, the generated random number is a binary random number, the black dots represent 0 and the white dots represent 1. As shown in FIG. 9, the black dots and the white dots in the schematic diagram are evenly distributed and there is no region where the black dots or the white dots are densely distributed, which indicates that the generated random number has good randomness.

In the process of implementing the m-th writing operation in the step S130, because the behavior of the analog resistive random access memory is unstable, it may also be difficult to set or reset the analog resistive random access memory. In this case, a method of setting a set pulse number threshold and a reset pulse number threshold may be used to avoid the random number generation process from falling into an endless loop, and the method of setting the set pulse number threshold and the reset pulse number threshold does not affect the randomness of the generated random number. For example, in an example of the method for generating a random number provided by the present disclosure, the step S100 may include a step S140.

Step S140: under the premise that the m-th writing operation described in the step S110 or S120 includes a set operation, the m-th writing operation further includes a reset operation, the at least one writing operation pulse corresponding to the m-th writing operation further includes at least one reset pulse, and the reset operation includes: obtaining a reset pulse number threshold; and sequentially applying the at least one reset pulse to the operated analog resistive random access memory until the conductance value of the operated analog resistive random access memory is gradually decreased from the set state conductance value to a reset target conductance value or a quantity of the at least one reset pulse reaches the reset pulse number threshold.

For example, the set state conductance value is greater than 20 μS, and the reset target conductance value is less than 10 μS, but the embodiments of the present disclosure are not limited to this.

For example, the reset pulse number threshold may be 20, but the embodiments of the present disclosure are not limited to this. The reset pulse number threshold may also be 15, 25, . . . 100, 1000, etc.

For example, the reset pulse number threshold and the set pulse number threshold may be identical.

For example, in a case where the conductance value of the operated analog resistive random access memory changes to the reset target conductance value, the quantity of the applied reset pulses that has been recorded can be obtained to obtain the m-th reset pulse number corresponding to the m-th writing operation, or the quantity of the applied reset pulses that has been recorded reaches the reset pulse number threshold, in this case, the quantity of the applied reset pulses that has been recorded (that is, the reset pulse number threshold) is the m-th reset pulse number corresponding to the m-th writing operation.

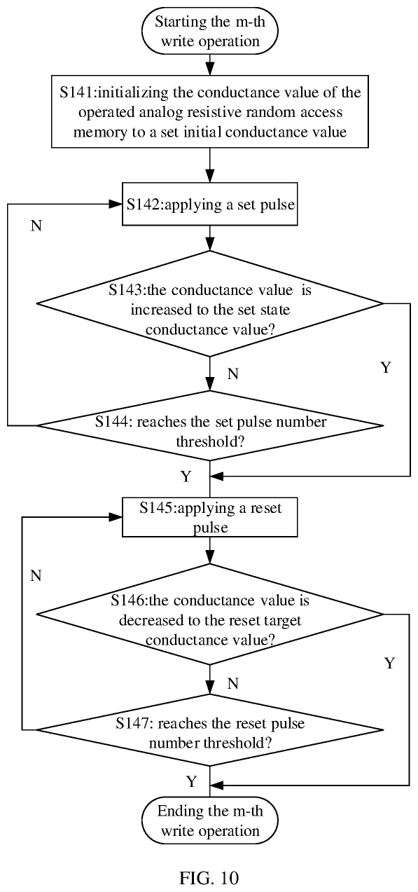

For example, FIG. 10 illustrates a flow diagram of the m-th writing operation in the step S140. As shown in FIG. 10, at a step S141, initializing the conductance value of the operated analog resistive random access memory to a set initial conductance value; at a step S142, applying a set pulse to the operated analog resistive random access memory after initialization; at a step S143, determining whether the conductance value of the operated analog resistive random access memory is increased to the set state conductance value, if yes, proceeding to a step S145, if not, proceeding to a step S144; at the step S144, determining whether the set pulse number reaches the set pulse number threshold, if yes, proceeding to the step S145, if not, returning to the step S142; in the step S145, applying a reset pulse to the operated analog resistive random access memory; at a step S146, determining whether the conductance value of the operated analog resistive random access memory is decreased to the reset target conductance value, if yes, ending the m-th writing operation, if not, proceeding to a step S147; at the step S147, determining whether the reset pulse number reaches the reset pulse number threshold, if yes, ending the m-th writing operation, if not, returning to the step S145.

For example, for the step S130 and the step S140, the set initial conductance value and the reset target conductance value may be equal. In this case, after one of the n writing operations is completed, the step of applying a set pulse in the next writing operation can be directly performed on the same analog resistive random access memory, thereby saving the step of initializing the conductance value of the operated analog resistive random access memory to the set initial conductance value in the next writing operation.

The above example shows an implementation manner in which each of the n writing operations includes only a set operation, and an implementation manner in which each of the n writing operations includes a combination of a set operation and a reset operation. It should be noted that each of the n writing operations may also include only a reset operation. For example, in an example of the method for generating a random number provided by the present disclosure, the step S100 may include a step S150.

Step S150: the m-th writing operation of the n writing operations includes a reset operation, and at least one writing operation pulse corresponding to the m-th writing operation includes at least one reset pulse, m is a positive integer, and 1≤m≤n, the reset operation includes: sequentially applying the at least one reset pulse to the operated analog resistive random access memory until the conductance value of the operated analog resistive random access memory is gradually decreased from a set state conductance value to a reset target conductance value.

For example, the set state conductance value is greater than 20 μS, and the reset target conductance value is less than 10 μS, but the embodiments of the present disclosure are not limited to this. It should be noted that in a case where the n writing operations are all reset operations, the n set state conductance values corresponding to the n writing operations may be at least partially different, as long as the n set state conductance values are all greater than 20 μS, and the n reset target conductance values corresponding to the n writing operations may also be at least partially different, as long as the n reset target conductance values are all less than 10 μS. In addition, the set state conductance value in the step S110 and the set state conductance value in the step S150 may be different.

For example, in a case where the conductance value of the operated analog resistive random access memory changes to the reset target conductance value, the quantity of the applied reset pulses that has been recorded can be obtained to obtain the m-th writing operation pulse number corresponding to the m-th writing operation.

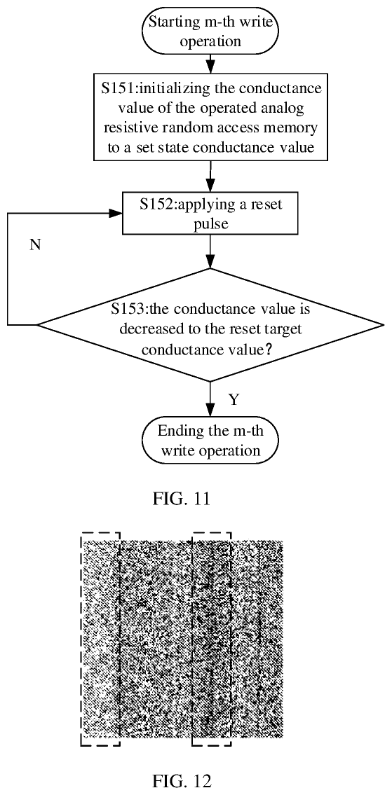

For example, FIG. 11 illustrates a flow diagram of the m-th writing operation in the step S150. As shown in FIG. 11, at a step S151, initializing the conductance value of the operated analog resistive random access memory to a set state conductance value; at a step S152, applying a reset pulse to the operated analog resistive random access memory after initialization; at a step S153, determining whether the conductance value of the operated analog resistive random access memory is decreased to the reset target conductance value, if yes, ending the m-th writing operation, if not, returning to the step S152.

For example, FIG. 12 illustrates a schematic diagram of a random number generated based on the writing operation flow shown in FIG. 11. In FIG. 12, the generated random number is a binary random number, the black dots represent 0 and the white dots represent 1. As shown in FIG. 12, the black dots and the white dots in the schematic diagram are basically evenly distributed, which indicates that the generated random number is unbiased and random. However, in the schematic diagram of FIG. 12, there is a region where white dots are dense and a region where black dots are dense (the regions enclosed by the dashed frames in FIG. 12). The region where the white dots are dense means that the generated random number 1 in this region is more than the generated random number 0, the region where the black dots are dense means that the generated random number 0 in this region is more than the generated random number 1. The reason for this phenomenon is that there are differences in the characteristics of different analog resistive random access memories. The writing operation pulse number that needs to be applied when some analog resistive random access memories are set has good randomness, but the writing operation pulse number that needs to be applied when some analog resistive random access memories are reset has poor randomness; while the writing operation pulse number that needs to be applied when some analog resistive random access memories are reset has good randomness, but the writing operation pulse number that needs to be applied when some analog resistive random access memories are set has poor randomness.

In the process of implementing the m-th writing operation in the step S150, because the behavior of the analog resistive random access memory is unstable, it may also be difficult to reset the analog resistive random access memory. In this case, a method of setting a reset pulse number threshold can be used to avoid the random number generation process from falling into an endless loop, and the method of setting the reset pulse number threshold does not affect the randomness of the generated random number. For example, in an example of the method for generating a random number provided by the present disclosure, the step S100 may include a step S160.

Step S160: the m-th writing operation of the n writing operations includes a reset operation, and at least one writing operation pulse corresponding to the m-th writing operation includes at least one reset pulse, m is a positive integer, and 1≤m≤n, the reset operation includes: obtaining a reset pulse number threshold; and sequentially applying the at least one reset pulse to the operated analog resistive random access memory until the conductance value of the operated analog resistive random access memory is gradually decreased from a set state conductance value to a reset target conductance value or a quantity of the at least one reset pulse reaches the reset pulse number threshold.

For example, the set state conductance value is greater than 20 μS, and the reset target conductance value is less than 10 μS, but the embodiments of the present disclosure are not limited to this.

For example, the reset pulse number threshold is 20, but the embodiments of the present disclosure are not limited to this.

For example, in a case where the conductance value of the operated analog resistive random access memory changes to the reset target conductance value, the quantity of the applied reset pulses that has been recorded can be obtained to obtain the m-th writing operation pulse number corresponding to the m-th writing operation, or the quantity of the applied reset pulses that has been recorded reaches the reset pulse number threshold, in this case, the quantity of the applied reset pulses that has been recorded (that is, the reset pulse number threshold) is the m-th writing operation pulse number corresponding to the m-th writing operation.

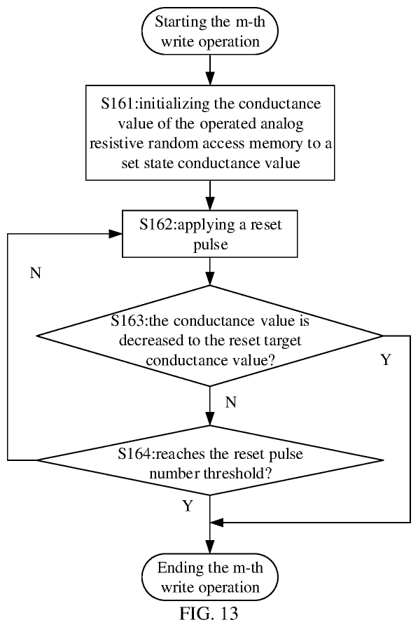

For example, FIG. 13 illustrates a flow diagram of the m-th writing operation in the step S160. As shown in FIG. 13, at a step S161, initializing the conductance value of the operated analog resistive random access memory to a set state conductance value; at a step S162, applying a reset pulse to the operated analog resistive random access memory after initialization; at a step S163, determining whether the conductance value of the operated analog resistive random access memory is decreased to the reset target conductance value, if yes, ending the m-th writing operation, if not, proceeding to a step S164; at the step S164, determining whether the reset pulse number reaches the reset pulse number threshold, if yes, ending the m-th writing operation, if not, returning to the step S162.

For the step S200, using the randomness of the writing operation pulse number to generate the random number may have different implementations. For example, computation processing can be performed on the writing operation pulse number, so that each writing operation generates one or more bits of a binary random number. For example, the computation processing may be an arithmetic computation processing, such as an addition computation, a subtraction computation, a multiplication computation, a division computation, a modulo computation (for example, a modulo N computation, N is a positive integer), etc.

For example, in an example of the method for generating a random number provided by the present disclosure, the step S200 may include a step S210.

Step S210: obtaining n intermediate numbers based on the n writing operation pulse numbers respectively corresponding to the n writing operations; and generating the random number according to the n intermediate numbers.

In the step S210, for example, for an i-th writing operation of the n writing operations, i is a positive integer and 1≤i≤n, the n intermediate numbers include an i-th intermediate number corresponding to the i-th writing operation, the n writing operation pulse numbers include an i-th writing operation pulse number corresponding to the i-th writing operation, in a case where the i-th writing operation only includes a set operation, the i-th writing operation pulse number includes a set pulse number corresponding to the set operation, and the i-th intermediate number is obtained by performing a first computation on the set pulse number, or in a case where the i-th writing operation only includes a reset operation, the i-th writing operation pulse number includes a reset pulse number corresponding to the reset operation, and the i-th intermediate number is obtained by performing a second computation on the reset pulse number, or in a case where the i-th writing operation includes a set operation and a reset operation, the i-th writing operation pulse number includes a set pulse number corresponding to the set operation and a reset pulse number corresponding to the reset operation, a computation result is obtained performing by a third computation on the set pulse number and the reset pulse number, and the i-th intermediate number is obtained by performing a fourth computation on the computation result.

For example, in an example of the method for generating a random number provided by the present disclosure, the third computation includes a summation operation, that is, adding the set pulse number and the reset pulse number. The computation result obtained by adding the set pulse number and the reset pulse number is random. Therefore, the operation can be continued based on the computation result to obtain an intermediate number with randomness. It should be noted that the third computation may also be other computation methods such as subtraction computation and multiplication computation, which are not limited in the embodiments of the present disclosure.

For example, in an example of the method for generating a random number provided by the present disclosure, the first computation, the second computation, and the fourth computation include a modulo 2^{L} computation, in which L is a positive integer, and generating the random number according to the n intermediate numbers includes: respectively taking the n intermediate numbers as n digits of an n-bit 2^{L}-ary number, and generating the random number based on the n-bit 2^{L}-ary number. For example, in a case where the first computation, the second computation, and the fourth computation are modulo 4 computations, the modulo 4 computation is performed on the n writing operation pulse numbers corresponding to the n writing operations to obtain n quaternary intermediate numbers, and the n quaternary intermediate numbers are respectively used as n digits of an n-digit quaternary number. For example, the n-digit quaternary number can be converted into a 2*n-digit binary number to generate a 2*n-digit binary random number.

For example, the first computation, the second computation, and the fourth computation are modulo 2 computations, and the modulo 2 computation is performed on the n writing operation pulse numbers corresponding to the n writing operations to obtain n binary intermediate numbers (that is, the Odevity of the writing operation pulse number, for example, if the writing operation pulse number is an odd number, the modulo 2 computation is performed on the writing operation pulse number to obtain 1; and if the writing operation pulse number is an even number, the modulo 2 computation is performed on the writing operation pulse number to obtain 0), the n binary intermediate numbers can be directly output as n digits of the binary random number.

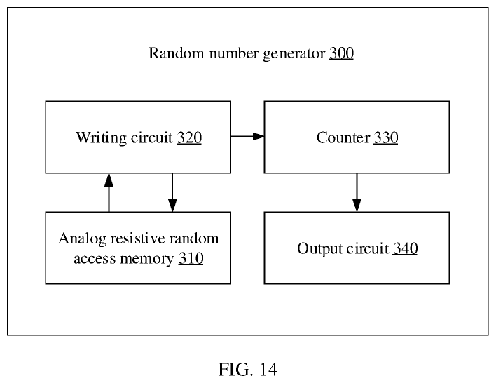

FIG. 14 is a schematic block diagram of a random number generator provided by at least one embodiment of the present disclosure. For example, as shown in FIG. 14, the random number generator 300 includes at least one analog resistive random access memory 310, a writing circuit 320, a counter 330, and an output circuit 340.

The writing circuit 320 is coupled to the at least one analog resistive random access memory 310, and is configured to perform n writing operations on the at least one analog resistive random access memory 310, and each of the n writing operations includes applying at least one writing operation pulse to change the conductance value of the operated analog resistive random access memory 310. For example, the writing circuit 320 can implement the step S100 in combination with the counter 330, and the specific implementation method can refer to the related descriptions of the step S100, which will not be repeated here.

The counter 330 is coupled to the writing circuit 320, and is configured to count writing operation pulses corresponding to the n writing operations to obtain n writing operation pulse numbers corresponding to the n writing operations, respectively. For example, the counter 330 can count the writing operation pulse corresponding to each writing operation in the step S100.

The output circuit 340 is coupled to the counter 330, and is configured to generate a random number based on the n writing operation pulse numbers, in which n is a positive integer. For example, the output circuit 340 can implement the step S200, and the specific implementation method can refer to the related descriptions of the step S200, which will not be repeated here.

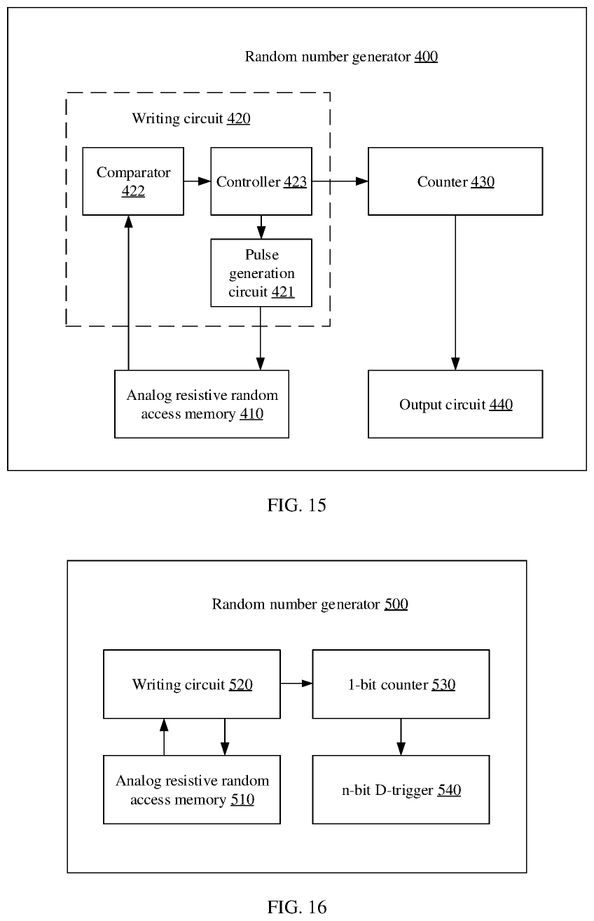

FIG. 15 is a schematic block diagram of an example of the random number generator shown in FIG. 14. As shown in FIG. 15, the writing circuit 420 includes a pulse generation circuit 421, a comparator 422, and a controller 423. For example, the writing circuit 420 can be implemented by a memory chip, because the pulse generation circuit, the comparator, and the controller are integrated in the memory chip. For example, the analog resistive random access memory 410 may also be integrated in the memory chip.

For example, in the random number generator provided by at least one embodiment of the present disclosure, an m-th writing operation of the n writing operations includes a set operation, at least one writing operation pulse corresponding to the m-th writing operation includes at least one set pulse, m is a positive integer, and 1≤m≤n, the n writing operation pulse numbers include an m-th writing operation pulse number corresponding to the m-th writing operation, the controller 423 is configured to control the pulse generation circuit 421 to generate and apply the at least one set pulse to the operated analog resistive random access memory 410, so that the conductance value of the operated analog resistive random access memory 410 is gradually increased from a set initial conductance value to a set state conductance value, and configured to control the counter to count the at least one set pulse to obtain an m-th set pulse number, and the m-th writing operation pulse number includes the m-th set pulse number; the comparator 422 is configured to compare the conductance value of the operated analog resistive random access memory 410 with a set state conductance value threshold to obtain a set comparison result; and the controller 423 is further configured to control the counter 430 to output the m-th set pulse number obtained by counting to the output circuit 440 in a case where the set comparison result indicates that the conductance value of the operated analog resistive random access memory 410 is increased to the set state conductance value.

For example, the set state conductance value is greater than 20 μS, and the set state conductance value threshold is 20 μS, but the embodiments of the present disclosure are not limited to this. For example, the writing circuit 420 can implement the step S110 in combination with the counter 430, and the specific implementation method can refer to the related descriptions of the step S110, which will not be repeated here.

For example, in the random number generator provided by at least one embodiment of the present disclosure, an m-th writing operation of the n writing operations includes a set operation, at least one writing operation pulse corresponding to the m-th writing operation includes at least one set pulse, m is a positive integer, and 1≤m≤n, the n writing operation pulse numbers include an m-th writing operation pulse number corresponding to the m-th writing operation, the controller 423 is configured to control the pulse generation circuit 421 to generate and apply the at least one set pulse to the operated analog resistive random access memory 410, so that the conductance value of the operated analog resistive random access memory 410 is gradually increased from a set initial conductance value to a set state conductance value, and configured to control the counter 430 to count the at least one set pulse to obtain an m-th set pulse number, and the m-th writing operation pulse number includes the m-th set pulse number; the comparator 422 is configured to compare the conductance value of the operated analog resistive random access memory 410 with a set state conductance value threshold to obtain a set comparison result; and the controller 423 is further configured to obtain a set pulse number threshold, and to control the counter 430 to output the m-th set pulse number obtained by counting to the output circuit 440 in a case where the set comparison result indicates that the conductance value of the operated analog resistive random access memory 410 is increased to the set state conductance value or the m-th set pulse number reaches the set pulse number threshold.

For example, the set state conductance value is greater than 20 μS, and the set state conductance value threshold is 20 μS, but the embodiments of the present disclosure are not limited to this. For example, the writing circuit 420 can implement the step S120 in combination with the counter 430, and the specific implementation method can refer to the related descriptions of the step S120, which will not be repeated here.

For example, in the random number generator provided by at least one embodiment of the present disclosure, on the premise that the m-th writing operation includes a set operation, the m-th writing operation further includes a reset operation, and the writing operation pulse further includes a reset pulse, the controller 423 is configured to control the pulse generation circuit 421 to generate and apply the at least one reset pulse to the operated analog resistive random access memory 410, so that the conductance value of the operated analog resistive random access memory 410 is gradually decreased from the set state conductance value to a reset target conductance value, and configured to control the counter 430 to count the at least one reset pulse to obtain an m-th reset pulse number, and the m-th writing operation pulse number further includes the m-th reset pulse number; the comparator 422 is configured to compare the conductance value of the operated analog resistive random access memory 410 with a reset target conductance value threshold to obtain a reset comparison result; the controller 423 is further configured to control the counter 430 to output the m-th reset pulse number obtained by counting to the output circuit 440 in a case where the reset comparison result indicates that the conductance value of the operated analog resistive random access memory 410 is decreased to the reset target conductance value.

For example, the reset target conductance value is less than 10 μS, and the reset target conductance value threshold is 10 μS, but the embodiments of the present disclosure are not limited to this. For example, the writing circuit 420 can implement the step S130 in combination with the counter 430, and the specific implementation method can refer to the related descriptions of the step S130, which will not be repeated here.

For example, in the random number generator provided by at least one embodiment of the present disclosure, on the premise that the m-th writing operation includes a set operation, the m-th writing operation further includes a reset operation, and the writing operation pulse further includes a reset pulse, the controller 423 is configured to control the pulse generation circuit 421 to generate and apply the at least one reset pulse to the operated analog resistive random access memory 410, so that the conductance value of the operated analog resistive random access memory is gradually decreased from the set state conductance value to the reset target conductance value, and configured to control the counter 430 to count the at least one reset pulse to obtain an m-th reset pulse number, and the m-th writing operation pulse number further includes the m-th reset pulse number; the comparator 422 is configured to compare the conductance value of the operated analog resistive random access memory 410 with a reset target conductance value threshold to obtain a reset comparison result; the controller 423 is further configured to obtain a reset pulse number threshold, and control the counter 430 to output the m-th reset pulse number obtained by counting to the output circuit 440 in a case where the reset comparison result indicates that the conductance value of the operated analog resistive random access memory is decreased to the reset target conductance value or the m-th reset pulse number reaches the reset pulse number threshold.

For example, the reset target conductance value is less than 10 μS, and the reset target conductance value threshold is 10 μS, but the embodiments of the present disclosure are not limited to this. For example, the writing circuit 420 can implement the step S140 in combination with the counter 430, and the specific implementation method can refer to the related descriptions of the step S140, which will not be repeated here.

For example, in the implementation manner in which the writing circuit 420 and the counter 430 implement the step S130 or S140, the set initial conductance value and the reset target conductance value may be equal. In this case, after one of the n writing operations is completed, the step of applying a set pulse in the next writing operation can be directly performed on the same analog resistive random access memory, thereby saving the step of initializing the conductance value of the operated analog resistive random access memory 410 to the set initial conductance value in the next writing operation.

For example, in the random number generator provided by at least one embodiment of the present disclosure, an m-th writing operation of the n writing operations includes a reset operation, at least one writing operation pulse corresponding to the m-th writing operation includes at least one reset pulse, m is a positive integer, and 1≤m≤n, the n writing operation pulse numbers include an m-th writing operation pulse number corresponding to the m-th writing operation, the controller 423 is configured to control the pulse generation circuit 421 to generate and apply the at least one reset pulse to the operated analog resistive random access memory 410, so that the conductance value of the operated analog resistive random access memory is gradually decreased from the set state conductance value to a reset target conductance value, and configured to control the counter 430 to count the at least one reset pulse to obtain a m-th reset pulse number, and the m-th writing operation pulse number includes the m-th reset pulse number; the comparator 422 is configured to compare the conductance value of the operated analog resistive random access memory 410 with a reset target conductance value threshold to obtain a reset comparison result; the controller 423 is further configured to control the counter 430 to output the m-th reset pulse number obtained by counting to the output circuit 440 in a case where the reset comparison result indicates that the conductance value of the operated analog resistive random access memory 410 is decreased to the reset target conductance value.

For example, the reset target conductance value is less than 10 μS, and the reset target conductance value threshold is 10 μS, but the embodiments of the present disclosure are not limited to this. For example, the writing circuit 420 can implement the step S150 in combination with the counter 430, and the specific implementation method can refer to the related descriptions of the step S150, which will not be repeated here.

For example, in the random number generator provided by at least one embodiment of the present disclosure, an m-th writing operation of the n writing operations includes a reset operation, at least one writing operation pulse corresponding to the m-th writing operation includes at least one reset pulse, m is a positive integer, and 1≤m≤n, the n writing operation pulse numbers include an m-th writing operation pulse number corresponding to the m-th writing operation, the controller 423 is configured to control the pulse generation circuit 421 to generate and apply the at least one reset pulse to the operated analog resistive random access memory 410, so that the conductance value of the operated analog resistive random access memory 410 is gradually decreased from the set state conductance value to a reset target conductance value, and configured to control the counter 430 to count the at least one reset pulse to obtain an m-th reset pulse number, and the m-th writing operation pulse number includes the m-th reset pulse number; the comparator 422 is configured to compare the conductance value of the operated analog resistive random access memory 410 with a reset target conductance value threshold to obtain a reset comparison result; the controller 423 is further configured to obtain a reset pulse number threshold, and control the counter 430 to output the m-th set pulse number obtained by counting to the output circuit 440 in a case where the set comparison result indicates that the conductance value of the operated analog resistive random access memory 410 is decreased to the reset target conductance value or the m-th reset pulse number reaches the reset pulse number threshold.

For example, the reset target conductance value is less than 10 μS, and the reset target conductance value threshold is 10 μS, but the embodiments of the present disclosure are not limited to this. For example, the writing circuit 420 can implement the step S160 in combination with the counter 430, and the specific implementation method can refer to the related descriptions of the step S160, which will not be repeated here.

For example, in the random number generator provided by at least one embodiment of the present disclosure, the output circuit 340 is configured to obtain n intermediate numbers based on the writing operation pulse numbers of the n writing operations, and generate the random number based on the n intermediate numbers. For example, the output circuit 340 may include a calculation circuit and a register, the calculation circuit is configured to perform computations on the writing operation pulse numbers of the n writing operations to obtain the n intermediate numbers, and the register is configured to register the n intermediate numbers to output the random number. For example, the output circuit 340 can implement the step S210, and the specific implementation method can refer to the related descriptions of the step S210, which will not be repeated here.

For example, in the random number generator provided by at least one embodiment of the present disclosure, for an i-th writing operation, i is a positive integer and 1≤i≤n, and the output circuit 340 may include the calculation circuit, and the calculation circuit is configured to: in a case where the i-th writing operation only includes a set operation, perform a first computation on a quantity of set pulses of the set operation to obtain an intermediate number corresponding to the i-th writing operation, or in a case where the i-th writing operation only includes a reset operation, perform a second computation on a quantity of reset pulses of the reset operation to obtain an intermediate number corresponding to the i-th writing operation, or in a case where the i-th writing operation comprises a set operation and a reset operation, perform a third computation on a quantity of set pulses of the set operation and a quantity of reset pulses of the reset operation to obtain a computation result, and perform a fourth computation on the computation result to obtain an intermediate number corresponding to the i-th writing operation.

For example, in the random number generator provided by at least one embodiment of the present disclosure, the output circuit 340 may include an adder, and the adder is configured to accumulate the quantity of set pulses of the set operation and the quantity of reset pulses of the reset operation to achieve the third computation.

For example, in the random number generator provided by at least one embodiment of the present disclosure, the output circuit 340 may include a calculation circuit and a register, the calculation circuit is configured to include a modulo 2^{L} computation circuit. The modulo 2^{L} computation circuit is used to perform a modulo 2^{L} computation to achieve the first computation, the second computation, and the fourth computation. L is a positive integer, so that n intermediate numbers with a bit width of L are obtained. The register is configured to have a bit width of L and a depth of n, and to register the n intermediate numbers with a bit width of L, that is, the register is configured to use the n intermediate numbers as respective digits of an n-bit 2^{L}-ary number, respectively, and then the register is configured to output the n intermediate numbers with the bit width of L stored in the register bit by bit, that is, the binary random number is generated based on the n-bit 2^{L}-ary number.

For example, FIG. 16 illustrates a schematic block diagram of an example of a random number generator. As shown in FIG. 16, the counter includes a 1-bit counter 530 (1 bit counter), and the output circuit includes an n-bit D-trigger 540, the 1-bit counter 530 is configured to perform modulo-2 counting on writing operation pulses corresponding to the n writing operations, so as to obtain the n writing operation pulse numbers corresponding to the n writing operations; in this case, the n writing operation pulse numbers corresponding to the n writing operations are modulo 2 values after modulo 2 operations. The modulo 2 values are 0 or 1, that is, in a case where the applied writing operation pulse number is an even number, the writing operation pulse number corresponds to 0, and in a case where the applied writing operation pulse number is an odd number, the writing operation pulse number corresponds to 1. The n-bit D-trigger is configured to output the n writing operation pulse numbers as the random number. In this example, the writing operation pulse number counted by the 1-bit counter 530 is the modulo 2 value, so that the 1-bit counter can obtain the 1-bit binary intermediate number while counting, and the operation process of obtaining the intermediate number by the output circuit is omitted. It should be noted that in a case where the writing operation includes a set operation and a reset operation, the 1-bit counter can directly count the reset pulse of the reset operation after completing counting the set pulse of the set operation, and therefore the modulo 2 addition computation or modulo 2 subtraction computation on the number of the set pulse of the set operation and the number of the reset pulse of the reset operation is achieved. Therefore, in the case where the writing operation includes the set operation and the reset operation, the operation process of obtaining the intermediate number by the output circuit is also omitted. In this case, the output circuit can be simply implemented as an n-bit D trigger 540, and the n-bit D trigger 540 is configured to directly output the n writing operation pulse numbers obtained by the 1-bit counter as the n bits of the random number. Of course, in this case, the output circuit may also be simply implemented as a 1-bit D trigger, which is configured to output 1 bit of the random number after each of the n writing operations is completed.

It should be noted that, for the sake of clarity and conciseness, the embodiments of the present disclosure do not provide all the constituent units of the random number generators 300, 400, and 500. In order to implement the necessary functions of the random number generators 300, 400, and 500, those skilled in the art can provide and set other unshown component units according to specific needs, and the embodiments of the present disclosure is not limited in this aspect.

For the technical effects of the random number generators 300, 400, or 500 in different embodiments, reference may be made to the technical effects of the method for generating a random number provided by the embodiments of the present disclosure, which will not be repeated here.

The following statements should be noted:

(1) The accompanying drawings of the embodiments of the present disclosure involve only the structure(s) in connection with the embodiment(s) of the present disclosure, and other structure(s) can refer to common design(s).

(2) In case of no conflict, the embodiments of the present disclosure and the features in the embodiment(s) can be combined with each other to obtain new embodiment(s).

What have been described above are only exemplary implementations of the present disclosure and are not used to limit the protection scope of the present disclosure, and the protection scope of the present disclosure should be based on the protection scope of the claims.

1. A method for generating a random number, comprising:
performing n writing operations on at least one analog resistive random access memory, wherein each of the n writing operations comprises applying at least one writing operation pulse to change a conductance value of an operated analog resistive access memory; and
generating the random number based on n writing operation pulse numbers respectively corresponding to the n writing operations, wherein n is a positive integer.

2. The method according to claim 1, wherein an m-th writing operation of the n writing operations comprises a set operation, and at least one writing operation pulse corresponding to the m-th writing operation comprises at least one set pulse, m is a positive integer, and 1≤m≤n, and the set operation comprises:
sequentially applying the at least one set pulse to the operated analog resistive random access memory until the conductance value of the operated analog resistive random access memory is gradually increased from a set initial conductance value to a set state conductance value.

3. The method according to claim 1, wherein an m-th writing operation of the n writing operations comprises a set operation, and at least one writing operation pulse corresponding to the m-th writing operation comprises at least one set pulse, m is a positive integer, and 1≤m≤n, and the set operation comprises:
obtaining a set pulse number threshold; and
sequentially applying the at least one set pulse to the operated analog resistive random access memory until the conductance value of the operated analog resistive random access memory is gradually increased from a set initial conductance value to a set state conductance value or a quantity of the at least one set pulse reaches the set pulse number threshold.

4. The method according to claim 2, wherein the m-th writing operation further comprises a reset operation, the at least one writing operation pulse corresponding to the m-th writing operation further comprises at least one reset pulse, and the reset operation comprises:
sequentially applying the at least one reset pulse to the operated analog resistive random access memory until the conductance value of the operated analog resistive random access memory is gradually decreased from the set state conductance value to a reset target conductance value.

5. The method according to claim 2, wherein the m-th writing operation further comprises a reset operation, the at least one writing operation pulse corresponding to the m-th writing operation further comprises at least one reset pulse, and the reset operation comprises:
obtaining a reset pulse number threshold; and
sequentially applying the at least one reset pulse to the operated analog resistive random access memory until the conductance value of the operated analog resistive random access memory is gradually decreased from the set state conductance value to a reset target conductance value or a quantity of the at least one reset pulse reaches the reset pulse number threshold.

6. (canceled)

7. The method according to claim 1, wherein an m-th writing operation of the n writing operations comprises a reset operation, and at least one writing operation pulse corresponding to the m-th writing operation comprises at least one reset pulse, m is a positive integer, and 1≤m≤n, and the reset operation comprises:
sequentially applying the at least one reset pulse to the operated analog resistive random access memory until the conductance value of the operated analog resistive random access memory is gradually decreased from a set state conductance value to a reset target conductance value.

8. The method according to claim 1, wherein an m-th writing operation of the n writing operations comprises a reset operation, and at least one writing operation pulse corresponding to the m-th writing operation comprises at least one reset pulse, m is a positive integer, and 1≤m≤n, and the reset operation comprises:
obtaining a reset pulse number threshold; and
sequentially applying the at least one reset pulse to the operated analog resistive random access memory until the conductance value of the operated analog resistive random access memory is gradually decreased from a set state conductance value to a reset target conductance value or a quantity of the at least one reset pulse reaches the reset pulse number threshold.

9. The method according to claim 1, wherein the generating the random number based on the n writing operation pulse numbers respectively corresponding to the n writing operations comprises:
obtaining n intermediate numbers based on the n writing operation pulse numbers respectively corresponding to the n writing operations; and
generating the random number according to the n intermediate numbers.

10. The method according to claim 9, wherein for an i-th writing operation of the n writing operations, i is a positive integer and 1≤i≤n, and the n intermediate numbers comprise an i-th intermediate number corresponding to the i-th writing operation, the n writing operation pulse numbers comprise an i-th writing operation pulse number corresponding to the i-th writing operation,
in a case where the i-th writing operation only comprises a set operation, the i-th writing operation pulse number comprises a set pulse number corresponding to the set operation, and the i-th intermediate number is obtained by performing a first computation on the set pulse number, or
in a case where the i-th writing operation only comprises a reset operation, the i-th writing operation pulse number comprises a reset pulse number corresponding to the reset operation, and the i-th intermediate number is obtained by performing a second computation on the reset pulse number, or
in a case where the i-th writing operation comprises a set operation and a reset operation, the i-th writing operation pulse number comprises a set pulse number corresponding to the set operation and a reset pulse number corresponding to the reset operation, a computation result is obtained by performing a third computation on the set pulse number and the reset pulse number, and the i-th intermediate number is obtained by performing a fourth computation on the computation result.

11. (canceled)

12. The method according to claim 10 or 11, wherein the first computation, the second computation, and the fourth computation comprise a modulo 2^{L} computation, wherein L is a positive integer, and the generating the random number according to the n intermediate numbers comprises:
taking the n intermediate numbers as n digits of an n-bit 2^{L}-ary number, respectively, and generating the random number based on the n-bit 2^{L}-ary number.

13. A random number generator, comprising:
at least one analog resistive random access memory;
a writing circuit, coupled to the at least one analog resistive random access memory and configured to perform n writing operations on the at least one analog resistive random access memory, wherein each of the n writing operations comprises applying at least one writing operation pulse to change a conductance value of an operated analog resistive random access memory;
a counter, coupled to the writing circuit and configured to count writing operation pulses corresponding to the n writing operations to obtain n writing operation pulse numbers corresponding to the n writing operations, respectively; and
an output circuit, coupled to the counter and configured to generate a random number based on the n writing operation pulse numbers, wherein n is a positive integer.

14. The random number generator according to claim 13, wherein the writing circuit comprises a pulse generation circuit, a comparator, and a controller,
wherein an m-th writing operation of the n writing operations comprises a set operation, at least one writing operation pulse corresponding to the m-th writing operation comprises at least one set pulse, m is a positive integer, and 1≤m≤n, the n writing operation pulse numbers comprise an m-th writing operation pulse number corresponding to the m-th writing operation,
the controller is configured to control the pulse generation circuit to generate and apply the at least one set pulse to the operated analog resistive random access memory, so that the conductance value of the operated analog resistive random access memory is gradually increased from a set initial conductance value to a set state conductance value, and configured to control the counter to count the at least one set pulse to obtain an m-th set pulse number, and the m-th writing operation pulse number comprises the m-th set pulse number;
the comparator is configured to compare the conductance value of the operated analog resistive random access memory with a set state conductance value threshold to obtain a set comparison result; and
the controller is further configured to control the counter to output the m-th set pulse number obtained by counting to the output circuit in a case where the set comparison result indicates that the conductance value of the operated analog resistive random access memory is increased to the set state conductance value.

15. The random number generator according to claim 13, wherein the writing circuit comprises a pulse generation circuit, a comparator, and a controller, wherein an m-th writing operation of the n writing operations comprises a set operation, at least one writing operation pulse corresponding to the m-th writing operation comprises at least one set pulse, m is a positive integer, and 1≤m≤n, the n writing operation pulse numbers comprise an m-th writing operation pulse number corresponding to the m-th writing operation,
the controller is configured to control the pulse generation circuit to generate and apply the at least one set pulse to the operated analog resistive random access memory, so that the conductance value of the operated analog resistive random access memory is gradually increased from a set initial conductance value to a set state conductance value, and configured to control the counter to count the at least one set pulse to obtain an m-th set pulse number, and the m-th writing operation pulse number comprises the m-th set pulse number;
the comparator is configured to compare the conductance value of the operated analog resistive random access memory with a set state conductance value threshold to obtain a set comparison result;
the controller is further configured to obtain a set pulse number threshold, and control the counter to output the m-th set pulse number obtained by counting to the output circuit in a case where the set comparison result indicates that the conductance value of the operated analog resistive random access memory is increased to the set state conductance value or the m-th set pulse number reaches the set pulse number threshold.

16. The random number generator according to claim 14, wherein the m-th writing operation further comprises a reset operation, and the at least one writing operation pulse further comprises at least one reset pulse,
the controller is configured to control the pulse generation circuit to generate and apply the at least one reset pulse to the operated analog resistive random access memory, so that the conductance value of the operated analog resistive random access memory is gradually decreased from the set state conductance value to a reset target conductance value, and configured to control the counter to count the at least one reset pulse to obtain an m-th reset pulse number, and the m-th writing operation pulse number further comprises the m-th reset pulse number;
the comparator is configured to compare the conductance value of the operated analog resistive random access memory with a reset target conductance value threshold to obtain a reset comparison result;
the controller is further configured to control the counter to output the m-th reset pulse number obtained by counting to the output circuit in a case where the reset comparison result indicates that the conductance value of the operated analog resistive random access memory is decreased to the reset target conductance value.

17. The random number generator according to claim 14, wherein the m-th writing operation further comprises a reset operation, and the at least one writing operation pulse further comprises at least one reset pulse,
the controller is configured to control the pulse generation circuit to generate and apply the at least one reset pulse to the operated analog resistive random access memory, so that the conductance value of the operated analog resistive random access memory is gradually decreased from the set state conductance value to a reset target conductance value, and configured to control the counter to count the at least one reset pulse to obtain an m-th reset pulse number, and the m-th writing operation pulse number further comprises the m-th reset pulse number;
the comparator is configured to compare the conductance value of the operated analog resistive random access memory with a reset target conductance value threshold to obtain a reset comparison result;
the controller is further configured to obtain a reset pulse number threshold, and control the counter to output the m-th reset pulse number obtained by counting to the output circuit in a case where the reset comparison result indicates that the conductance value of the operated analog resistive random access memory is decreased to the reset target conductance value or the m-th reset pulse number reaches the reset pulse number threshold.

18. (canceled)

19. The random number generator according to claim 13, wherein the writing circuit comprises a pulse generation circuit, a comparator, and a controller, wherein an m-th writing operation of the n writing operations comprises a reset operation, at least one writing operation pulse corresponding to the m-th writing operation comprises at least one reset pulse, m is a positive integer, and 1≤m≤n, the n writing operation pulse numbers comprise an m-th writing operation pulse number corresponding to the m-th writing operation,
the controller is configured to control the pulse generation circuit to generate and apply the at least one reset pulse to the operated analog resistive random access memory, so that the conductance value of the operated analog resistive random access memory is gradually decreased from a set state conductance value to a reset target conductance value, and configured to control the counter to count the at least one reset pulse to obtain a m-th reset pulse number, and the m-th writing operation pulse number comprises the m-th reset pulse number;
the comparator is configured to compare the conductance value of the operated analog resistive random access memory with a reset target conductance value threshold to obtain a reset comparison result;
the controller is further configured to control the counter to output the m-th reset pulse number obtained by counting to the output circuit in a case where the reset comparison result indicates that the conductance value of the operated analog resistive random access memory is decreased to the reset target conductance value.

20. The random number generator according to claim 13, wherein the writing circuit comprises a pulse generation circuit, a comparator, and a controller, wherein an m-th writing operation of the n writing operations comprises a reset operation, at least one writing operation pulse corresponding to the m-th writing operation comprises at least one reset pulse, m is a positive integer, and 1≤m≤n, the n writing operation pulse numbers comprise an m-th writing operation pulse number corresponding to the m-th writing operation,
the controller is configured to control the pulse generation circuit to generate and apply the at least one reset pulse to the operated analog resistive random access memory, so that the conductance value of the operated analog resistive random access memory is gradually decreased from a set state conductance value to a reset target conductance value, and configured to control the counter to count the at least one reset pulse to obtain an m-th reset pulse number, and the m-th writing operation pulse number comprises the m-th reset pulse number;
the comparator is configured to compare the conductance value of the operated analog resistive random access memory with a reset target conductance value threshold to obtain a reset comparison result;
the controller is further configured to obtain a reset pulse number threshold, and control the counter to output the m-th reset pulse number obtained by counting to the output circuit in a case where the reset comparison result indicates that the conductance value of the operated analog resistive random access memory is decreased to the reset target conductance value or the m-th reset pulse number reaches the reset pulse number threshold.

21. The random number generator according to claim 13, wherein the output circuit is configured to: obtain n intermediate numbers based on the n writing operation pulse numbers respectively corresponding to the n writing operations, and generate the random number based on the n intermediate numbers.

22. The random number generator according to claim 21, wherein for an i-th writing operation, i is a positive integer and 1≤i≤n, and the output circuit is configured to:
in a case where the i-th writing operation only comprises a set operation, perform a first computation on a quantity of set pulses of the set operation to obtain an intermediate number corresponding to the i-th writing operation, or
in a case where the i-th writing operation only comprises a reset operation, perform a second computation on a quantity of reset pulses of the reset operation to obtain an intermediate number corresponding to the i-th writing operation, or
in a case where the i-th writing operation comprises a set operation and a reset operation, perform a third computation on a quantity of set pulses of the set operation and a quantity of reset pulses of the reset operation to obtain a computation result, and perform a fourth computation on the computation result to obtain an intermediate number corresponding to the i-th writing operation.

23. (canceled)

24. (canceled)

25. The random number generator according to claim 13, wherein the counter comprises a 1-bit counter, and the output circuit comprises an n-bit D-trigger,
the 1-bit counter is configured to perform modulo-2 counting on writing operation pulses corresponding to the n writing operations, to obtain the n writing operation pulse numbers corresponding to the n writing operations; and
the n-bit D-trigger is configured to output the n writing operation pulse numbers as the random number.
